(19) United States
(12) Patent Application Publication
(10) Pub. No.: US 2025/0202737 A1
(43) Pub. Date: Jun. 19, 2025

(54) NONLINEAR MODELING FOR CHANNEL ESTIMATION

(71) Applicant: QUALCOMM INCORPORATED, San Diego, CA (US)

(72) Inventors: Igor GUTMAN, Hod HaSharon (IL); Juergen CEZANNE, Ocean Township, NJ (US); Joseph Patrick BURKE, Carlsbad, CA (US); Pushkar Bajirao KULKARNI, San Diego, CA (US); Abdelrahman Mohamed Ahmed Mohamed IBRAHIM, San Diego, CA (US); Junyi LI, Greentown, PA (US)

(21) Appl. No.: 18/849,706

(22) PCT Filed: May 10, 2023
(86) PCT No.: PCT/US2023/021707

§ 371 Date: Sep. 23, 2024

(30) Foreign Application Priority Data
Jun. 1, 2022 (IL) 293537

(51) Int. Cl. H04L 25/02; H03F 1/32

(52) U.S. Cl. CPC H04L 25/0226; H03F 1/32; H04L 25/024; H03F 2200/451

(57) ABSTRACT

Various aspects of the present disclosure generally relate to wireless communication. In some aspects, a network node may transmit a nonlinear modeling capability indication associated with a nonlinear modeling configuration of the network node. The network node may receive, based on the nonlinear modeling capability indication, a communication in a slot, wherein the communication includes a data signal and at least one demodulation reference signal (DMRS), wherein the at least one DMRS is associated with a single transmission power value. Numerous other aspects are described.

### CROSS-REFERENCE TO RELATED APPLICATION

This Patent application claims priority to Israeli Patent Application No. 293537, filed on Jun. 1, 2022, entitled “NONLINEAR MODELING FOR CHANNEL ESTIMATION,” and assigned to the assignee hereof. The disclosure of the prior Application is considered part of and is incorporated by reference into this Patent Application.

### FIELD OF THE DISCLOSURE

Aspects of the present disclosure generally relate to wireless communication and to techniques and apparatuses for nonlinear modeling for channel estimation.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more base stations that support communication for a user equipment (UE) or multiple UEs. A UE may communicate with a base station via downlink communications and uplink communications. “Downlink” (or “DL”) refers to a communication link from the base station to the UE, and “uplink” (or “UL”) refers to a communication link from the UE to the base station.

The above multiple access technologies have been adopted in various telecommunication standards to provide a common protocol that enables different UEs to communicate on a municipal, national, regional, and/or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

### SUMMARY

Some aspects described herein relate to a network node for wireless communication. The network node may include a memory and one or more processors coupled to the memory. The one or more processors may be configured to transmit a nonlinear modeling capability indication associated with a nonlinear modeling configuration of the network node. The one or more processors may be configured to receive, based on the nonlinear modeling capability indication, a communication in a slot, wherein the communication includes a data signal and at least one demodulation reference signal (DMRS), wherein the at least one DMRS is associated with a single transmission power value.

Some aspects described herein relate to a method of wireless communication performed by a network node. The method may include transmitting a nonlinear modeling capability indication associated with a nonlinear modeling configuration of the network node. The method may include receiving, based on the nonlinear modeling capability indication, a communication in a slot, wherein the communication includes a data signal and at least one DMRS, wherein the at least one DMRS is associated with a single transmission power value.

Some aspects described herein relate to a non-transitory computer-readable medium that stores a set of instructions for wireless communication by a network node. The set of instructions, when executed by one or more processors of the network node, may cause the network node to transmit a nonlinear modeling capability indication associated with a nonlinear modeling configuration of the network node. The set of instructions, when executed by one or more processors of the network node, may cause the network node to receive, based on the nonlinear modeling capability indication, a communication in a slot, wherein the communication includes a data signal and at least one DMRS, wherein the at least one DMRS is associated with a single transmission power value.

Some aspects described herein relate to an apparatus for wireless communication. The apparatus may include means for transmitting a nonlinear modeling capability indication associated with a nonlinear modeling configuration of the apparatus. The apparatus may include means for receiving, based on the nonlinear modeling capability indication, a communication in a slot, wherein the communication includes a data signal and at least one DMRS, wherein the at least one DMRS is associated with a single transmission power value.

Aspects generally include a method, apparatus, system, computer program product, non-transitory computer-readable medium, user equipment, base station, wireless communication device, and/or processing system as substantially described herein with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example environment, in accordance with the present disclosure.

FIG. 2 is a diagram illustrating example components of an apparatus, in accordance with the present disclosure.

FIG. 3 is a diagram illustrating an example of a wireless network, in accordance with the present disclosure.

FIG. 4 is a diagram illustrating an environment including a network node in wireless communication with another network node, in accordance with the present disclosure.

FIG. 5 is a diagram illustrating an example of an open-radio access network architecture, in accordance with the present disclosure.

FIG. 6 is a diagram illustrating an example of wireless communication, in accordance with the present disclosure.

FIG. 7 is a diagram illustrating an example associated with nonlinear modeling for channel estimation, in accordance with the present disclosure.

FIG. 8 is a diagram illustrating an example process associated with nonlinear modeling for channel estimation, in accordance with the present disclosure.

FIG. 9 is a diagram of an example apparatus for wireless communication, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Aspects and examples generally include a method, apparatus, network node, system, computer program product, non-transitory computer-readable medium, user equipment, base station, wireless communication device, and/or processing system as described or substantially described herein with reference to and as illustrated by the drawings and specification.

This disclosure may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, are better understood from the following description when considered in connection with the accompanying figures. Each of the figures is provided for the purposes of illustration and description, and not as a definition of the limits of the claims.

While aspects are described in the present disclosure by illustration to some examples, such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component-based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). Aspects described herein may be practiced in a wide variety of devices, components, systems, distributed arrangements, and/or end-user devices of varying size, shape, and constitution.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, or the like (collectively referred to as “elements”). These elements may be implemented using hardware, software, or combinations thereof. Whether such elements are implemented as hardware or software depends upon the particular application and design constraints imposed on the overall system.

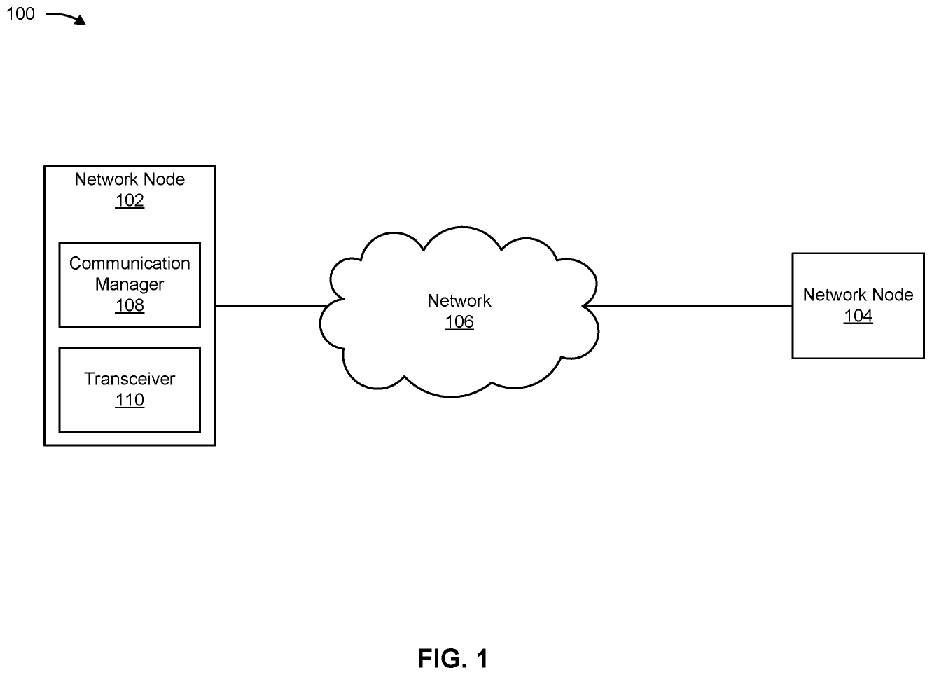

FIG. 1 is a diagram illustrating an example environment 100 in which apparatuses and/or methods described herein may be implemented, in accordance with the present disclosure. As shown in FIG. 1, the environment 100 may include a network node 102 and a network node 104 that may communicate with one another via a network 106. The network nodes 102 and 104 may be dispersed throughout the network 106, and each network node 102 and/or 104 may be stationary and/or mobile. The network 106 may include wired communication connections, wireless communication connections, or a combination of wired and wireless communication connections.

The network 106 may include, for example, a cellular network (e.g., a Long-Term Evolution (LTE) network, a code division multiple access (CDMA) network, a 3G network, a 4G network, a 5G network, another type of next generation network, and/or the like), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, and/or a combination of these or other types of networks.

In general, any number of networks 106 may be deployed in a given geographic area. Each network 106 may support a particular radio access technology (RAT) and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, Open-RAT, New Radio (NR) or 5G RAT networks may be deployed.

In some aspects, the environment 100 may include one or more non-terrestrial network (NTN) deployments in which a non-terrestrial wireless communication device may include a network node. The network node may include a UE (which may be referred to herein, interchangeably, as a “non-terrestrial UE”), a base station (referred to herein, interchangeably, as a “non-terrestrial BS” and “non-terrestrial base station”), and/or a relay station (referred to herein, interchangeably, as a “non-terrestrial relay station”), among other examples. As used herein, “NTN” may refer to a network for which access is facilitated by a non-terrestrial UE, non-terrestrial base station, and/or a non-terrestrial relay station, among other examples.

One or more of the network nodes 102 and 104 may be, include, of be included in any number of non-terrestrial wireless communication devices. A non-terrestrial wireless communication device may include a satellite, a manned aircraft system, an unmanned aircraft system (UAS) platform, and/or the like. A satellite may include a low-earth orbit (LEO) satellite, a medium-earth orbit (MEO) satellite, a geostationary earth orbit (GEO) satellite, a high elliptical orbit (HEO) satellite, and/or the like. A manned aircraft system may include an airplane, helicopter, a dirigible, and/or the like. A UAS platform may include a high-altitude platform station (HAPS), and may include a balloon, a dirigible, an airplane, and/or the like. Satellites may communicate directly and/or indirectly with other entities in the environment using satellite communication. The other entities may include UEs (e.g., terrestrial UEs and/or non-terrestrial UEs), other satellites in the one or more NTN deployments, other types of base stations (e.g., stationary and/or ground-based BSs), relay stations, and/or one or more components and/or devices included in a core network, among other examples.

As described herein, a node (which may be referred to as a node, a network node, a network entity, or a wireless node) may include, be, or be included in (e.g., be a component of) a base station (e.g., any base station described herein), a UE (e.g., any UE described herein), a network controller, an apparatus, a device, a computing system, an integrated access and backhauling (IAB) node, a distributed unit (DU), a central unit (CU), a remote/radio unit (RU) (which may also be referred to as a remote radio unit (RRU)), and/or another processing entity configured to perform any of the techniques described herein. For example, a network node may be a UE. As another example, a network node may be a base station or network entity. As another example, a first network node may be configured to communicate with a second network node or a third network node. In one aspect of this example, the first network node may be a UE, the second network node may be a base station, and the third network node may be a UE. In another aspect of this example, the first network node may be a UE, the second network node may be a base station, and the third network node may be a base station. In yet other aspects of this example, the first, second, and third network nodes may be different relative to these examples. Similarly, reference to a UE, base station, apparatus, device, computing system, or the like may include disclosure of the UE, base station, apparatus, device, computing system, or the like being a network node. For example, disclosure that a UE is configured to receive information from a base station also discloses that a first network node is configured to receive information from a second network node. Consistent with this disclosure, once a specific example is broadened in accordance with this disclosure (e.g., a UE is configured to receive information from a base station also discloses that a first network node is configured to receive information from a second network node), the broader example of the narrower example may be interpreted in the reverse, but in a broad open-ended way. In the example above where a UE is configured to receive information from a base station also discloses that a first network node is configured to receive information from a second network node, the first network node may refer to a first UE, a first base station, a first apparatus, a first device, a first computing system, a first set of one or more one or more components, a first processing entity, or the like configured to receive the information; and the second network node may refer to a second UE, a second base station, a second apparatus, a second device, a second computing system, a second set of one or more components, a second processing entity, or the like.

As described herein, communication of information (e.g., any information, signal, or the like) may be described in various aspects using different terminology. Disclosure of one communication term includes disclosure of other communication terms. For example, a first network node may be described as being configured to transmit information to a second network node. In this example and consistent with this disclosure, disclosure that the first network node is configured to transmit information to the second network node includes disclosure that the first network node is configured to provide, send, output, communicate, or transmit information to the second network node. Similarly, in this example and consistent with this disclosure, disclosure that the first network node is configured to transmit information to the second network node includes disclosure that the second network node is configured to receive, obtain, or decode the information that is provided, sent, output, communicated, or transmitted by the first network node.

As shown, the network node 102 may include a communication manager 108 configured to perform one or more communication tasks as described herein.

In some aspects, the network node may include a communication manager 108 and/or a transceiver 110. In some aspects, the communication manager 108 may include the transceiver 110 or one or more components thereof. In some aspects, the communication manager 108 may be implemented as hardware, software, or a combination of hardware and software, and may be configured to control one or more operations of the transceiver. For example, as described in more detail elsewhere herein, the communication manager 108 and/or the transceiver 110 may transmit a nonlinear modeling capability indication associated with a nonlinear modeling configuration of the network node; and receive, based on the nonlinear modeling capability indication, a communication in a slot, wherein the communication includes a data signal and at least one demodulation reference signal (DMRS), wherein the at least one DMRS is associated with a single transmission power value. Additionally, or alternatively, the communication manager 108 and/or the transceiver 110 may perform one or more other operations described herein.

The number and arrangement of entities shown in FIG. 1 are provided as one or more examples. In practice, there may be additional network nodes and/or networks, fewer network nodes and/or networks, different network nodes and/or networks, or differently arranged network nodes and/or networks than those shown in FIG. 1. Furthermore, the network node 102 and/or 104 may be implemented using a single apparatus or multiple apparatuses.

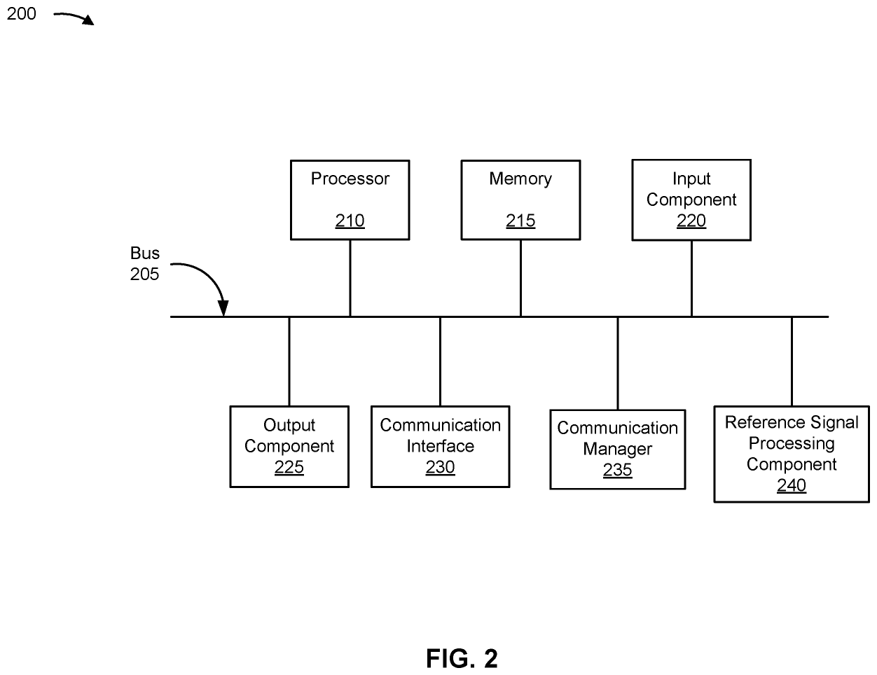

FIG. 2 is a diagram of example components of an apparatus 200. The apparatus 200 may correspond to the network node 102 and/or the network node 104. Additionally, or alternatively, the network node 102 and/or the network node 104 may include one or more apparatuses 200 and/or one or more components of the apparatus 200. For example, in some aspects, the apparatus 200 may include an apparatus (e.g., a device, a device component, a modem, a chip, and/or a set of device components, among other examples) that is configured to perform a wireless communication method at a network node, as described herein. As shown in FIG. 2, the apparatus 200 may include components such as a bus 205, a processor 210, a memory 215, an input component 220, an output component 225, a communication interface 230, a communication manager 235, and a reference signal processing component 240. Any one or more of the components 205, 210, 215, 220, 225 230, 235, and/or 240 may be implemented in hardware, software, or a combination of hardware and software.

The bus 205 includes a component that permits communication among the components of the apparatus 200. The processor 210 includes a central processing unit (CPU), a graphics processing unit (GPU), an accelerated processing unit (APU), a digital signal processor (DSP), a microprocessor, a microcontroller, a field-programmable gate array (FPGA), an application-specific integrated circuit (ASIC), and/or another type of processing component. In some aspects, the processor 210 includes one or more processors capable of being programmed to perform a function.

The memory 215 includes a random-access memory (RAM), a read only memory (ROM), and/or another type of dynamic or static storage device (e.g., a flash memory, a magnetic memory, and/or an optical memory) that stores information and/or instructions for use by the processor 210. The memory 215 may store other information and/or software related to the operation and use of the apparatus 200. For example, the memory 215 may include a hard disk (e.g., a magnetic disk, an optical disk, a magneto-optic disk, and/or a solid-state disk), a compact disc (CD), a digital versatile disc (DVD), a floppy disk, a cartridge, a magnetic tape, and/or another type of non-transitory computer-readable medium.

The input component 220 includes a component that permits the apparatus 200 to receive information, such as via user input. For example, the input component 220 may be associated with a user interface as described herein (e.g., to permit a user to interact with the one or more features of the apparatus 200). The input component 220 may include a capacitive touchscreen display that can receive user inputs. The input component 220 may include a keyboard, a keypad, a mouse, a button, a switch, and/or a microphone, among other examples. Additionally, or alternatively, the input component 220 may include a sensor for sensing information (e.g., a vision sensor, a location sensor, an accelerometer, a gyroscope, and/or an actuator, among other examples). In some aspects, the input component 220 may include a camera (e.g., a high-resolution camera and/or a low-resolution camera, among other examples). The output component 225 may include a component that provides output from the apparatus 200 (e.g., a display, a speaker, and/or one or more light-emitting diodes (LEDs), among other examples).

The communication interface 230 may include a transmission component and/or a reception component. For example, the communication interface 230 may include a transceiver and/or one or more separate receivers and/or transmitters that enable the apparatus 200 to communicate with other devices, such as via a wired connection, a wireless connection, or a combination of wired and wireless connections. In some aspects, the communication interface may include one or more radio frequency reflective elements and/or one or more radio frequency refractive elements. The communication interface 230 may permit the apparatus 200 to receive information from another apparatus and/or provide information to another apparatus. For example, the communication interface 230 may include an Ethernet interface, an optical interface, a coaxial interface, an infrared interface, an RF interface, a universal serial bus (USB) interface, a Wi-Fi interface, a cellular network interface, a wireless modem, an inter-integrated circuit (I²C), and/or a serial peripheral interface (SPI), among other examples.

The communication manager 235 may include hardware, software, or a combination of hardware and software configured to cause the apparatus 200 to perform one or more communication tasks associated with communication manager 108 and/or the transceiver 110. In some aspects, the communication manager 235 may be, be similar to, include, or be included in, the communication manager 108 depicted in FIG. 1. In some aspects, the communication manager 235 may include the processor 210, the memory 215, the input component 220, the output component 225, the communication interface 230, and/or the reference signal processing component 240, and/or one or more aspects thereof.

As indicated above, FIG. 2 is provided as an example. Other examples may differ from what is described with regard to FIG. 2.

As described above, in some aspects, the network 106 depicted in FIG. 1 may include a cellular network that includes a RAT. While some aspects may be described herein using terminology commonly associated with a 5G or NR RAT, aspects of the present disclosure can be applied to other RATs, such as a 3G RAT, a 4G RAT, and/or a RAT subsequent to 5G (e.g., 6G).

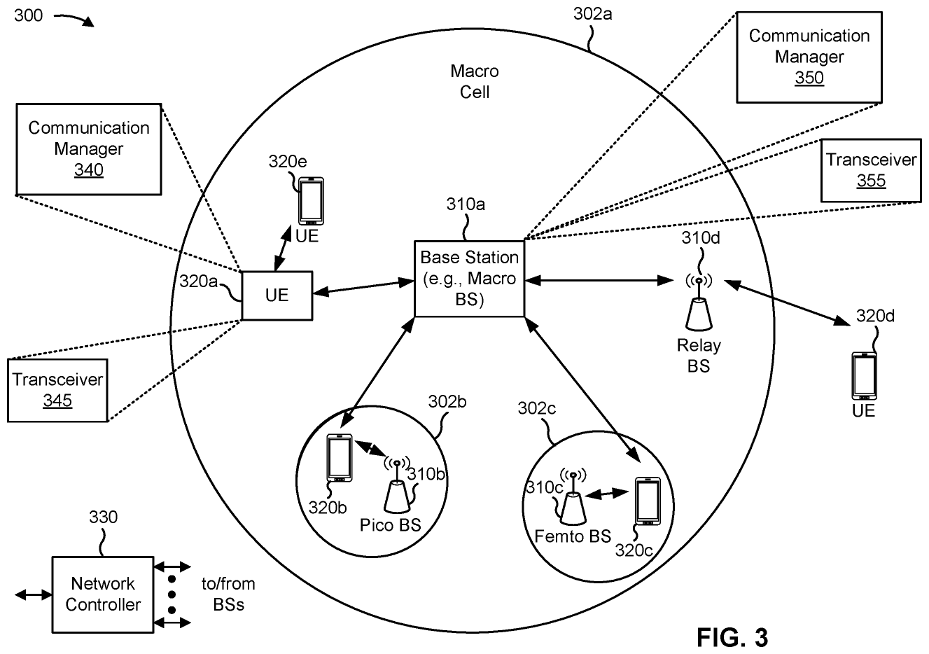

FIG. 3 is a diagram illustrating an example of a wireless network 300, in accordance with the present disclosure. The wireless network 300 may be or may include elements of a 4G (e.g., LTE) network, a 5G (e.g., NR) network, and/or a 6G network, among other examples. The wireless network 300 may include one or more base stations 310 (illustrated individually as a BS 310a, a BS 310b, a BS 310c, and a BS 310d), a UE 320 or multiple UEs 320 (illustrated individually as a UE 320a, a UE 320b, a UE 320c, a UE 320d, and a UE 320e), and/or other network entities. A base station 310 is an entity that communicates with UEs 320. A base station 310 may include, for example, an NR base station, an LTE base station, a Node B, an eNB (e.g., in 4G), a gNB (e.g., in 5G), an access point, and/or a transmission reception point (TRP). Each base station 310 may provide communication coverage for a particular geographic area. In the Third Generation Partnership Project (3GPP), the term “cell” can refer to a coverage area of a base station 310 and/or a base station subsystem serving the coverage area, depending on the context in which the term is used.

A base station 310 may provide communication coverage for a macro cell, a pico cell, a femto cell, and/or another type of cell. A macro cell may cover a relatively large geographic area (e.g., several kilometers in radius) and may allow unrestricted access by UEs 320 with service subscriptions. A pico cell may cover a relatively small geographic area and may allow unrestricted access by UEs 320 with service subscription. A femto cell may cover a relatively small geographic area (e.g., a home) and may allow restricted access by UEs 320 having association with the femto cell (e.g., UEs 320 in a closed subscriber group (CSG)). A base station 310 for a macro cell may be referred to as a macro base station. A base station 310 for a pico cell may be referred to as a pico base station. A base station 310 for a femto cell may be referred to as a femto base station or an in-home base station. In the example shown in FIG. 3, the BS 310a may be a macro base station for a macro cell 302a, the BS 310b may be a pico base station for a pico cell 302b, and the BS 310c may be a femto base station for a femto cell 302c. A base station may support one or multiple (e.g., three) cells.

In some examples, a cell may not necessarily be stationary, and the geographic area of the cell may move according to the location of a base station 310 that is mobile (e.g., a mobile base station). In some examples, the base stations 310 may be interconnected to one another and/or to one or more other base stations 310 or network nodes (not shown) in the wireless network 300 through various types of backhaul interfaces, such as a direct physical connection or a virtual network, using any suitable transport network.

The wireless network 300 may include one or more relay stations. A relay station is an entity that can receive a transmission of data from an upstream station (e.g., a base station 310 or a UE 320) and send a transmission of the data to a downstream station (e.g., a UE 320 or a base station 310). A relay station may be a UE 320 that can relay transmissions for other UEs 320. In the example shown in FIG. 3, the BS 310d (e.g., a relay base station) may communicate with the BS 310a (e.g., a macro base station) and the UE 320d in order to facilitate communication between the BS 310a and the UE 320d. A base station 310 that relays communications may be referred to as a relay station, a relay base station, a relay, or the like.

The wireless network 300 may be a heterogeneous network that includes base stations 310 of different types, such as macro base stations, pico base stations, femto base stations, relay base stations, or the like. These different types of base stations 310 may have different transmit power levels, different coverage areas, and/or different impacts on interference in the wireless network 300. For example, macro base stations may have a high transmit power level (e.g., 5 to 40 watts) whereas pico base stations, femto base stations, and relay base stations may have lower transmit power levels (e.g., 0.1 to 2 watts).

A network controller 330 may couple to or communicate with a set of base stations 310 and may provide coordination and control for these base stations 310. The network controller 330 may communicate with the base stations 310 via a backhaul communication link. The base stations 310 may communicate with one another directly or indirectly via a wireless or wireline backhaul communication link. For example, in some aspects, the wireless network 300 may be, include, or be included in a wireless backhaul network, sometimes referred to as an integrated access and backhaul (IAB) network. In an IAB network, at least one base station (e.g., base station 310) may be an anchor base station that communicates with a core network via a wired backhaul link, such as a fiber connection. An anchor base station may also be referred to as an IAB donor (or IAB-donor), a central entity, a central unit, and/or the like. An IAB network may include one or more non-anchor base stations, sometimes referred to as relay base stations or IAB nodes (or IAB-nodes). The non-anchor base station may communicate directly with or indirectly with (e.g., via one or more non-anchor base stations) the anchor base station via one or more backhaul links to form a backhaul path to the core network for carrying backhaul traffic. Backhaul links may be wireless links. Anchor base station(s) and/or non-anchor base station(s) may communicate with one or more UEs (e.g., UE 320) via access links, which may be wireless links for carrying access traffic.

In some aspects, a radio access network that includes an IAB network may utilize millimeter wave technology and/or directional communications (e.g., beamforming, precoding and/or the like) for communications between base stations and/or UEs (e.g., between two base stations, between two UEs, and/or between a base station and a UE). For example, wireless backhaul links between base stations may use millimeter waves to carry information and/or may be directed toward a target base station using beamforming, precoding, and/or the like. Similarly, wireless access links between a UE and a base station may use millimeter waves and/or may be directed toward a target wireless node (e.g., a UE and/or a base station). In this way, inter-link interference may be reduced.

An IAB network may include an IAB donor that connects to a core network via a wired connection (e.g., a wireline backhaul). For example, an Ng interface of an IAB donor may terminate at a core network. Additionally, or alternatively, an IAB donor may connect to one or more devices of the core network that provide a core access and mobility management function (AMF). In some aspects, an IAB donor may include a base station 310, such as an anchor base station. An IAB donor may include a central unit, which may perform access node controller (ANC) functions and/or AMF functions. The central unit may configure a distributed unit (DU) of the IAB donor and/or may configure one or more IAB nodes (e.g., a mobile termination (MT) function and/or a DU function of an IAB node) that connect to the core network via the IAB donor. Thus, a central unit of an IAB donor may control and/or configure the entire IAB network (or a portion thereof) that connects to the core network via the IAB donor, such as by using control messages and/or configuration messages (e.g., a radio resource control (RRC) configuration message or an F1 application protocol (FIAP) message).

The MT functions of an IAB node (e.g., a child node) may be controlled and/or scheduled by another IAB node (e.g., a parent node of the child node) and/or by an IAB donor. The DU functions of an IAB node (e.g., a parent node) may control and/or schedule other IAB nodes (e.g., child nodes of the parent node) and/or UEs 320. Thus, a DU may be referred to as a scheduling node or a scheduling component, and an MT may be referred to as a scheduled node or a scheduled component. In some aspects, an IAB donor may include DU functions and not MT functions. That is, an IAB donor may configure, control, and/or schedule communications of IAB nodes and/or UEs 320. A UE 320 may include only MT functions, and not DU functions. That is, communications of a UE 320 may be controlled and/or scheduled by an IAB donor and/or an IAB node (e.g., a parent node of the UE 320).

When a first node controls and/or schedules communications for a second node (e.g., when the first node provides DU functions for the second node's MT functions), the first node may be referred to as a parent node of the second node, and the second node may be referred to as a child node of the first node. A child node of the second node may be referred to as a grandchild node of the first node. Thus, a DU function of a parent node may control and/or schedule communications for child nodes of the parent node. A parent node may be an IAB donor or an IAB node, and a child node may be an IAB node or a UE 320. Communications of an MT function of a child node may be controlled and/or scheduled by a parent node of the child node.

A link between a UE 320 and an IAB donor, or between a UE 320 and an IAB node, may be referred to as an access link. An access link may be a wireless access link that provides a UE 320 with radio access to a core network via an IAB donor, and optionally via one or more IAB nodes. Thus, the wireless network 300 may be referred to as a multi-hop network or a wireless multi-hop network.

A link between an IAB donor and an IAB node or between two IAB nodes may be referred to as a backhaul link. A backhaul link may be a wireless backhaul link that provides an IAB node with radio access to a core network via an IAB donor, and optionally via one or more other IAB nodes. In an IAB network, network resources for wireless communications (e.g., time resources, frequency resources, and/or spatial resources) may be shared between access links and backhaul links. In some aspects, a backhaul link may be a primary backhaul link or a secondary backhaul link (e.g., a backup backhaul link). In some aspects, a secondary backhaul link may be used if a primary backhaul link fails, becomes congested, and/or becomes overloaded, among other examples.

The UEs 320 may be dispersed throughout the wireless network 300, and each UE 320 may be stationary or mobile. A UE 320 may include, for example, an access terminal, a terminal, a mobile station, and/or a subscriber unit. A UE 320 may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (e.g., a smart watch, smart clothing, smart glasses, a smart wristband, smart jewelry (e.g., a smart ring or a smart bracelet)), an entertainment device (e.g., a music device, a video device, and/or a satellite radio), a vehicular component or sensor, a smart meter/sensor, industrial manufacturing equipment, a global positioning system device, and/or any other suitable device that is configured to communicate via a wireless medium.

Some UEs 320 may be considered machine-type communication (MTC) or evolved or enhanced machine-type communication (eMTC) UEs. An MTC UE and/or an eMTC UE may include, for example, a robot, a drone, a remote device, a sensor, a meter, a monitor, and/or a location tag, that may communicate with a base station, another device (e.g., a remote device), or some other entity. Some UEs 320 may be considered Internet-of-Things (IoT) devices, and/or may be implemented as NB-IoT (narrowband IoT) devices. Some UEs 320 may be considered a customer premises equipment. A UE 320 may be included inside a housing that houses components of the UE 320, such as processor components and/or memory components. In some examples, the processor components and the memory components may be coupled together. For example, the processor components (e.g., one or more processors) and the memory components (e.g., a memory) may be operatively coupled, communicatively coupled, electronically coupled, and/or electrically coupled.

In general, any number of wireless networks 300 may be deployed in a given geographic area. Each wireless network 300 may support a particular RAT and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, NR or 5G RAT networks may be deployed.

In some examples, two or more UEs 320 (e.g., shown as UE 320a and UE 320e) may communicate directly using one or more sidelink channels (e.g., without using a base station 310 as an intermediary to communicate with one another). For example, the UEs 320 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, or a vehicle-to-pedestrian (V2P) protocol), and/or a mesh network. In such examples, a UE 320 may perform scheduling operations, resource selection operations, and/or other operations described elsewhere herein as being performed by the base station 310.

Devices of the wireless network 300 may communicate using the electromagnetic spectrum, which may be subdivided by frequency or wavelength into various classes, bands, channels, or the like. For example, devices of the wireless network 300 may communicate using one or more operating bands. In 5G NR, two initial operating bands have been identified as frequency range designations FR1 (410 MHZ-7.125 GHZ) and FR2 (24.25 GHZ-52.6 GHz). It should be understood that although a portion of FR1 is greater than 6 GHZ, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHZ-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHZ. For example, three higher operating bands have been identified as frequency range designations FR4a or FR4-1 (52.6 GHz-71 GHz). FR4 (52.6 GHZ-114.25 GHZ), and FR5 (114.25 GHz-300 GHz). Each of these higher frequency bands falls within the EHF band.

With the above examples in mind, unless specifically stated otherwise, it should be understood that the term “sub-6 GHz” or the like, if used herein, may broadly represent frequencies that may be less than 6 GHz, may be within FR1, or may include mid-band frequencies. Further, unless specifically stated otherwise, it should be understood that the term “millimeter wave” or the like, if used herein, may broadly represent frequencies that may include mid-band frequencies, may be within FR2, FR4, FR4-a or FR4-1, and/or FR5, or may be within the EHF band. It is contemplated that the frequencies included in these operating bands (e.g., FR1, FR2, FR3, FR4, FR4-a, FR4-1, and/or FR5) may be modified, and techniques described herein are applicable to those modified frequency ranges.

As described above, in some aspects, a network node (e.g., the network node 102 and/or the network node 104 depicted in FIG. 1) may be implemented in a wireless communication environment. For example, in some aspects, the network node may be implemented as a UE (e.g., UE 320a) a base station (e.g., base station 310a), relay device, and/or TRP, among other examples. In some such aspects, as shown in FIG. 3, the UE 320a may include a communication manager 340 and/or a transceiver 345 and the base station 310a may include a communication manager 350 and/or a transceiver 355. In some aspects, the communication manager 340 and/or 350 may be, be similar to, include, or be included in, the communication manager 108 depicted in FIG. 1 and/or the communication manager 235 depicted in FIG. 2. In some aspects, the transceiver 345 and/or 355 may be, be similar to, include, or be included in the transceiver 110 depicted in FIG. 1. In some aspects, the transceiver 345 and/or 355 may include, or be included in the communication interface 230 depicted in FIG. 2.

For example, in some aspects, one or more of the communication manager 340, the communication manager 350, the transceiver 345 and/or the transceiver 355 may transmit a nonlinear modeling capability indication associated with a nonlinear modeling configuration of the network node; and receive, based on the nonlinear modeling capability indication, a communication in a slot, wherein the communication includes a data signal and at least one DMRS, wherein the at least one DMRS is associated with a single transmission power value. Additionally, or alternatively, one or more of the communication manager 340, the communication manager 350, the transceiver 345 and/or the transceiver 355 may perform one or more other operations described herein.

As indicated above. FIG. 3 is provided as an example. Other examples may differ from what is described with regard to FIG. 3.

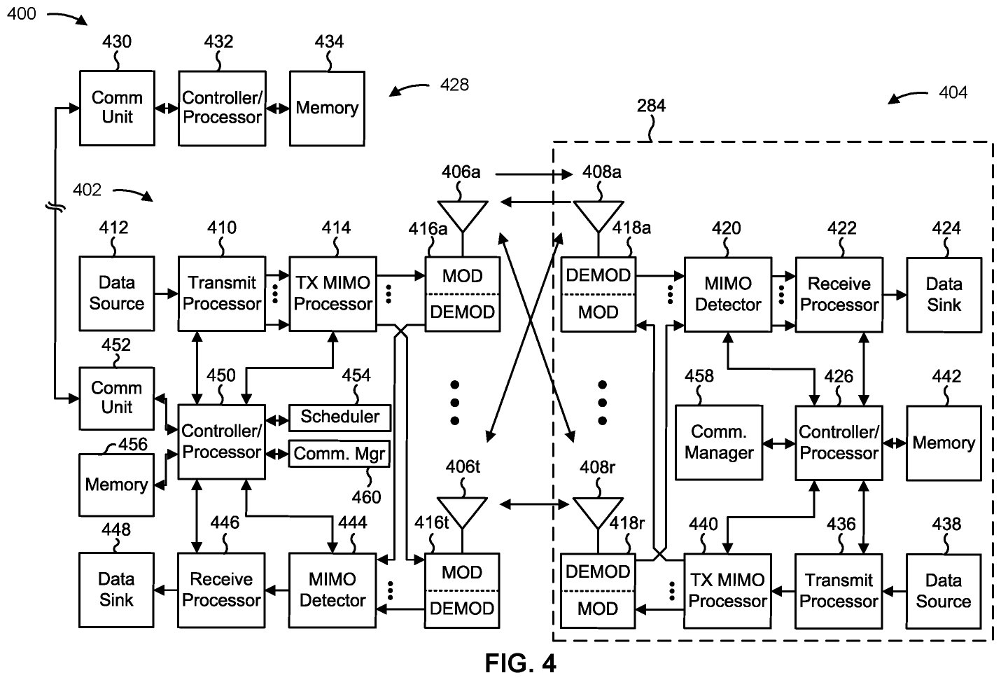

FIG. 4 is a diagram illustrating an environment 400 including a network node 402 in wireless communication with a network node 404 (e.g., via a network such as the network 106 depicted in FIG. 1 and/or the wireless network 300 depicted in FIG. 3), in accordance with the present disclosure. The network node 402 may be equipped with a set of antennas 406a through 406t, such as T antennas (T≥1). The network node 404 may be equipped with a set of antennas 408a through 408r, such as R antennas (R≥1).

At the network node 402, a transmit processor 410 may receive data, from a data source 412, intended for the network node 404 (or a set of network nodes 404). The transmit processor 410 may select one or more modulation and coding schemes (MCSs) for the network node 404 based on one or more channel quality indicators (CQIs) received from that network node 404. The network node 402 may process (e.g., encode and modulate) the data for the network node 404 based on the MCS(s) selected for the network node 404 and may provide data symbols for the network node 404. The transmit processor 410 may process system information (e.g., for semi-static resource partitioning information (SRPI)) and control information (e.g., CQI requests, grants, and/or upper layer signaling) and provide overhead symbols and control symbols. The transmit processor 410 may generate reference symbols for reference signals (e.g., a cell-specific reference signal (CRS) or a DMRS) and synchronization signals (e.g., a primary synchronization signal (PSS) or a secondary synchronization signal (SSS)). A transmit (TX) multiple-input multiple-output (MIMO) processor 414 may perform spatial processing (e.g., precoding) on the data symbols, the control symbols, the overhead symbols, and/or the reference symbols, if applicable, and may provide a set of output symbol streams (e.g., T output symbol streams) to a corresponding set of modems 416a through 416t (e.g., T modems). For example, each output symbol stream may be provided to a modulator component (shown as MOD) of a modem of the set of modems 416a through 416t. Each modem of the set of modems 416a through 416t may use a respective modulator component to process a respective output symbol stream (e.g., for OFDM) to obtain an output sample stream. Each modem of the set of modems 416a through 416t may further use a respective modulator component to process (e.g., convert to analog, amplify, filter, and/or upconvert) the output sample stream to obtain a signal. One or more modems of the set of modems 416a through 416t may transmit a set of signals (e.g., T signals) via a corresponding antenna of the set of antennas 406a through 406t. The signal may include, for example, a downlink signal.

At the network node 404, one or more antennas of the set of antennas 408a through 408r may receive the signals from the network node 402 and/or network nodes and may provide a set of received signals (e.g., R received signals) to one or more modems of a set of modems 418a through 418r (e.g., R modems). For example, each received signal may be provided to a demodulator component (shown as DEMOD) of a respective modem of the set of modems 418a through 418r. Each modem of the set of modems 418a through 418r may use a respective demodulator component to condition (e.g., filter, amplify, downconvert, and/or digitize) a received signal to obtain input samples. Each modem of the set of modems 418a through 418r may use a demodulator component to further process the input samples (e.g., for OFDM) to obtain received symbols. A MIMO detector 420 may obtain received symbols from one or more modems of the set of modems 418a through 418r, may perform MIMO detection on the received symbols if applicable, and may provide detected symbols.

A receive processor 422 may process (e.g., demodulate and decode) the detected symbols, may provide decoded data for the network node 404 to a data sink 424, and may provide decoded control information and system information to a controller/processor 426. The term “controller/processor” may refer to one or more controllers, one or more processors, or a combination thereof. The controller/processor 426 may be, be similar to, include, or be included in the processor 210 depicted in FIG. 2. The controller/processor 426 may determine a reference signal received power (RSRP) parameter, a received signal strength indicator (RSSI) parameter, a reference signal received quality (RSRQ) parameter, and/or a CQI parameter, among other examples.

A network controller 428 may include a communication unit 430, a controller/processor 432, and a memory 434. The network controller 428 may be, be similar to, include, or be included in the network controller 330 depicted in FIG. 3. The network controller 428 may include, for example, one or more devices in a core network. The network controller 428 may communicate with the network node 402 via the communication unit 430.

One or more antennas (e.g., antennas 406a through 406t and/or antennas 408a through 408r) may include, or may be included within, one or more antenna panels, one or more antenna groups, one or more sets of antenna elements, and/or one or more antenna arrays, among other examples. An antenna panel, an antenna group, a set of antenna elements, and/or an antenna array may include one or more antenna elements (within a single housing or multiple housings), a set of coplanar antenna elements, a set of non-coplanar antenna elements, and/or one or more antenna elements coupled to one or more transmission and/or reception components, such as one or more components of FIG. 4.

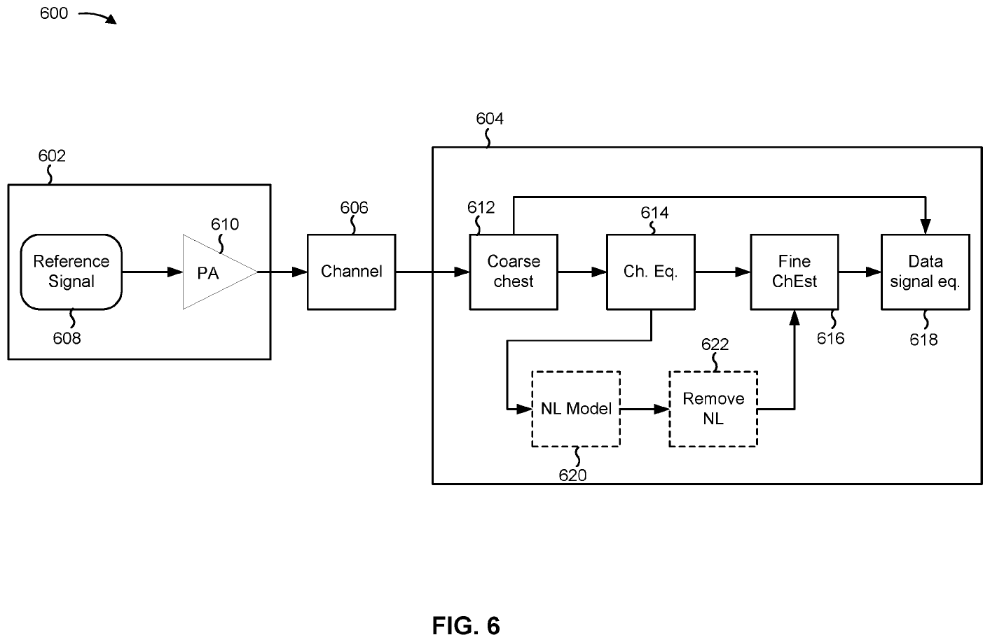

Similarly, at the network node 404, a transmit processor 436 may receive and process data from a data source 438 and control information (e.g., for reports that include RSRP. RSSI. RSRQ, and/or CQI) from the controller/processor 426. The transmit processor 436 may generate reference symbols for one or more reference signals. The symbols from the transmit processor 436 may be precoded by a TX MIMO processor 440 if applicable, and further processed by one or more of the set of modems 418a through 418r (e.g., for DFT-s-OFDM or CP-OFDM), and transmitted to the network node 402. In some examples, each modem of the set of modems 418a through 418r of the network node 404 may include a modulator and a demodulator. In some examples, the network node 404 includes a transceiver. The transceiver may include any combination of the antenna(s) 408a through 408r, the modem(s) 418a through 418r, the MIMO detector 420, the receive processor 422, the transmit processor 436, and/or the TX MIMO processor 440. The transceiver may be, be similar to, include, or be included in, the communication interface 230 depicted in FIG. 2. The transceiver may be used by a processor (e.g., the controller/processor 426) and/or a memory 442 to perform aspects of any of the methods described herein (e.g., with reference to FIGS. 6-9).

At the network node 402, the signals from network node 404 and/or other network nodes may be received by one or more antennas of the set of antennas 406a through 406t, processed by one or more modems of the set of modems 416a through 416t (e.g., a demodulator component, shown as DEMOD), detected by a MIMO detector 444 if applicable, and further processed by a receive processor 446 to obtain decoded data and control information sent by the network node 404. The receive processor 446 may provide the decoded data to a data sink 448 and provide the decoded control information to a controller/processor 450. The network node 402 may include a communication unit 452 and may communicate with the network controller 428 via the communication unit 452. The network node 402 may include a scheduler 454 to schedule one or more network nodes 404 for downlink and/or uplink communications. In some examples, one or more modems of the set of modem 416a through 416t of the network node 402 may include a modulator and a demodulator. In some examples, the network node 402 includes a transceiver. The transceiver may include any combination of the antenna(s) 406a through 406t, the modem(s) 416a through 416t, the MIMO detector 444, the receive processor 446, the transmit processor 410, and/or the TX MIMO processor 414. The transceiver may be, be similar to, include, or be included in the communication interface 230 depicted in FIG. 2. The transceiver may be used by a processor (e.g., the controller/processor 450) and a memory 456 to perform aspects of any of the methods described herein (e.g., with reference to FIGS. 6-9).

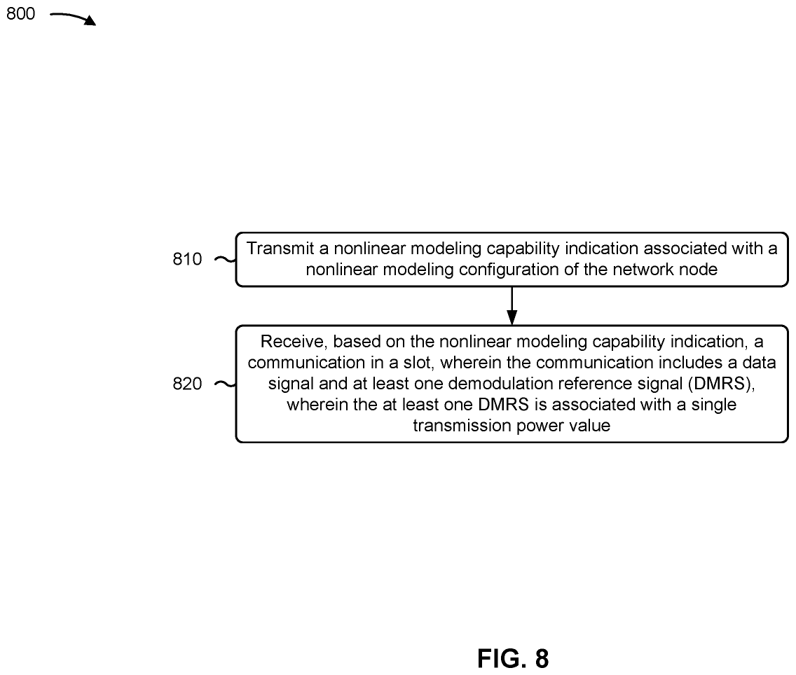

The controller/processor 450 of the network node 402, the controller/processor 426 of the network node 404, and/or any other component(s) of FIG. 4 may perform one or more techniques associated with nonlinear modeling for channel estimation, as described in more detail elsewhere herein. For example, the controller/processor 450 of the network node 402, the controller/processor 426 of the network node 404, and/or any other component(s) of FIG. 4 may perform or direct operations of, for example, process 800 of FIG. 8 and/or other processes as described herein. The memory 442 and the memory 456 may store data and program codes for the network node 402 and the network node 404, respectively. In some examples, the memory 442 and/or the memory 456 may include a non-transitory computer-readable medium storing one or more instructions (e.g., code and/or program code) for wireless communication. For example, the one or more instructions, when executed (e.g., directly, or after compiling, converting, and/or interpreting) by one or more respective processors of the network node 402 and/or the network node 404, may cause the one or more processors, the network node 404, and/or the network node 402 to perform or direct operations of, for example, process 800 of FIG. 8 and/or other processes as described herein. In some examples, executing instructions may include running the instructions, converting the instructions, compiling the instructions, and/or interpreting the instructions, among other examples.

In some aspects, the network node includes means for transmitting a nonlinear modeling capability indication associated with a nonlinear modeling configuration of the network node; and/or means for receiving, based on the nonlinear modeling capability indication, a communication in a slot, wherein the communication includes a data signal and at least one DMRS, wherein the at least one DMRS is associated with a single transmission power value. In some aspects, the means for the network node to perform operations described herein may include, for example, one or more of communication manager 458 or 460, transmit processor 410 or 436. TX MIMO processor 414 or 440, modem 416a-416t or 418a-418r, antenna 406a-406t or 408a-408r. MIMO detector 420 or 444, receive processor 422 or 446, controller/processor 426 or 450, memory 442 or 456, or scheduler 454.

While blocks in FIG. 4 are illustrated as distinct components, the functions described above with respect to the blocks may be implemented in a single hardware, software, or combination component or in various combinations of components. For example, the functions described with respect to the transmit processor 436, the receive processor 422, and/or the TX MIMO processor 440 may be performed by or under the control of the controller/processor 426. Any number of other combination of various combinations of components depicted in FIG. 4 may be within the ambit of the present disclosure.

As indicated above. FIG. 4 is provided as an example. Other examples may differ from what is described with regard to FIG. 4.

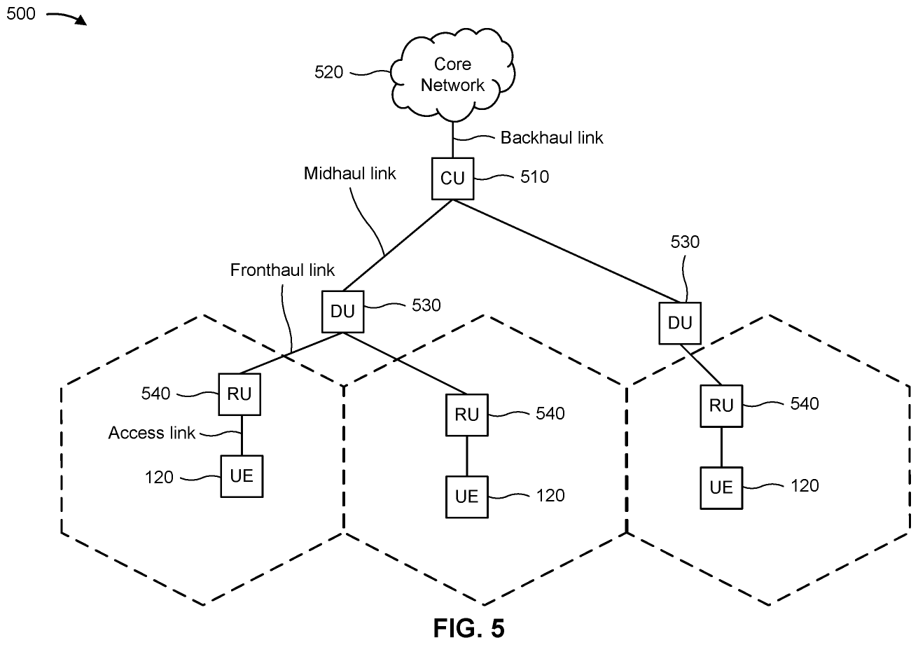

FIG. 5 is a diagram illustrating an example 500 of an O-RAN architecture, in accordance with the present disclosure. As shown in FIG. 5, the O-RAN architecture may include a control unit (CU) 510 that communicates with a core network 520 via a backhaul link. Furthermore, the CU 510 may communicate with one or more DUs 530 via respective midhaul links. The DUs 530 may each communicate with one or more radio units (RUs) 540 via respective fronthaul links, and the RUs 540 may each communicate with respective UEs 120 via RF access links. The DUs 530 and the RUs 540 may also be referred to as O-RAN DUs (O-DUs) 530 and O-RAN RUs (O-RUs) 540, respectively.

In some aspects, the DUs 530 and the RUs 540 may be implemented according to a functional split architecture in which functionality of a base station 310 (e.g., an eNB or a gNB) is provided by a DU 530 and one or more RUs 540 that communicate over a fronthaul link. Accordingly, as described herein, a base station 310 may include a DU 530 and one or more RUs 540 that may be co-located or geographically distributed. In some aspects, the DU 530 and the associated RU(s) 540 may communicate via a fronthaul link to exchange real-time control plane information via a lower layer split (LLS) control plane (LLS-C) interface, to exchange non-real-time management information via an LLS management plane (LLS-M) interface, and/or to exchange user plane information via an LLS user plane (LLS-U) interface.

Accordingly, the DU 530 may correspond to a logical unit that includes one or more base station functions to control the operation of one or more RUs 540. For example, in some aspects, the DU 530 may host a radio link control (RLC) layer, a medium access control (MAC) layer, and one or more high physical (PHY) layers (e.g., forward error correction (FEC) encoding and decoding, scrambling, and/or modulation and demodulation) based on a lower layer functional split. Higher layer control functions, such as a packet data convergence protocol (PDCP). RRC, and/or service data adaptation protocol (SDAP), may be hosted by the CU 510. The RU(s) 540 controlled by a DU 530 may correspond to logical nodes that host RF processing functions and low-PHY layer functions (e.g., fast Fourier transform (FFT), inverse FFT (IFFT), digital beamforming, and/or physical random access channel (PRACH) extraction and filtering) based on the lower layer functional split. Accordingly, in an O-RAN architecture, the RU(s) 540 handle all over the air (OTA) communication with a UE 120, and real-time and non-real-time aspects of control and user plane communication with the RU(s) 540 are controlled by the corresponding DU 530, which enables the DU(s) 530 and the CU 510 to be implemented in a cloud-based RAN architecture.

As indicated above. FIG. 5 is provided as an example. Other examples may differ from what is described with regard to FIG. 5.

FIG. 6 is a diagram illustrating an example 600 of wireless communication, in accordance with the present disclosure. As shown, a first network node 602 and a second network node 604 may communicate via a communication channel 606. As shown, for example, the network node 602 may generate a reference signal 608 for transmission via the channel 606. To transmit stronger signals, the network node 602 may include a high-power power amplifier (PA) 610. The reference signal may be boosted using the PA 610 before transmission via the channel 606.

The network node 604 may receive the reference signal 608, via the channel 606, and perform a coarse channel estimation 612 (shown as “coarse chest”). Coarse channel estimation is an initial channel estimation that is used to obtain an approximate estimate of the channel 606. The network node 604 may perform a channel equalization procedure 614 (shown as “ch. eq.”) on the coarse channel estimate to generate an equalized coarse channel estimate. A fine channel estimation procedure 616 (shown as “fine chest”) can be used to generate a more accurate channel estimation (e.g., a channel estimation with more granularity than that of the coarse channel estimate). The network node 604 can use the fine channel estimate to perform data signal equalization 618 (shown as “data signal eq.”) to facilitate demodulation and/or decoding of data signals associated with the reference signal 608.

In some cases, PAs 610 may have limited linear dynamic range (DR), and, as a result, may introduce non-linear characteristics to the reference signal. These nonlinear characteristics may be referred to as nonlinear distortion and may have a negative impact on coarse and fine channel estimation, as the distortions may be carried through the procedures. In order to avoid those nonlinear distortions, power output back-off (BO) can be introduced. However, the BO may reduce power efficiency. In some cases, digital post distortion (DPOD) procedures can be used to remove nonlinear distortions from a signal. However, without a model of the nonlinearity of the distortion. DPOD procedures may be ineffective at reducing the distortion and/or may result in degradation of the original signal. In some cases, a nonlinear estimation may be performed using reference signals that are transmitted on the same symbols as the data symbols but with a different power than the power with which the data signals are transmitted. Accordingly, a resulting channel estimation may not be accurate in terms of the data signals since the nonlinear modeling would have been performed on a signal that was not imparted with the same nonlinear distortions as the data signal.

Some aspects of the techniques and apparatuses described herein may provide a nonlinear modeling configuration for receiver network nodes that may be used to generate nonlinear models based on a reference signal transmitted at a same power as corresponding data signals. The nonlinear modeling configuration includes a reference signal processing component that may be configured to generate a nonlinear model 620 that provides information associated with, for example, nonlinear characteristics imparted by a PA and to use a nonlinear removal component 622 to remove the nonlinear characteristics from a received signal during a channel estimation procedure. As a result, aspects of the present disclosure may facilitate more accurate nonlinear modeling of distorted reference signals, thereby facilitating demodulation and/or decoding of corresponding data signals. Thus, aspects of the present disclosure may positively impact network performance.

As indicated above. FIG. 6 is provided as an example. Other examples may differ from what is described with regard to FIG. 6.

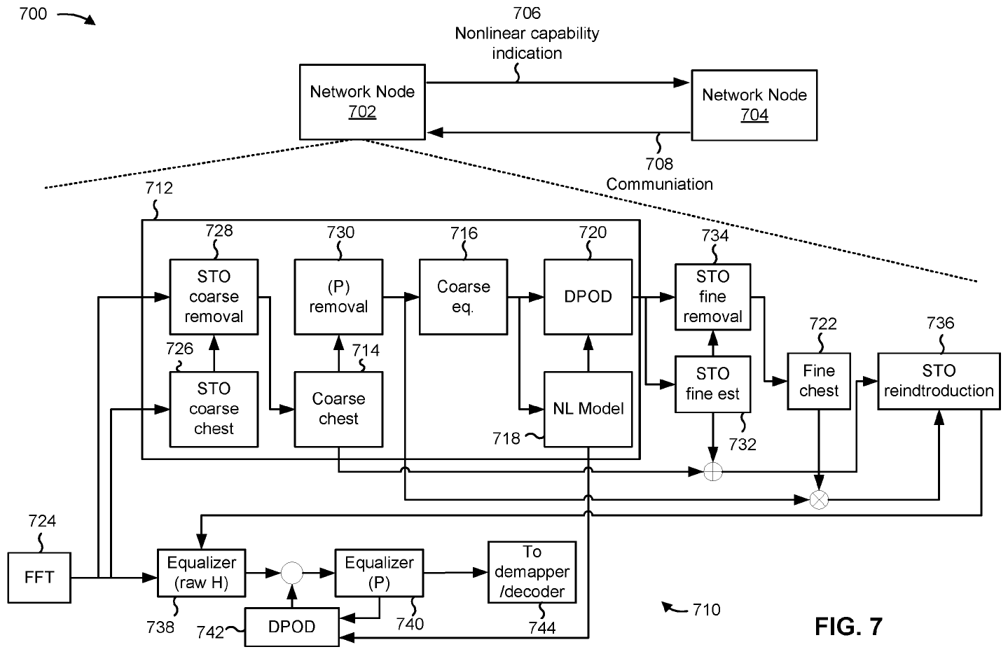

FIG. 7 is a diagram illustrating an example 700 associated with nonlinear modeling for channel estimation, in accordance with the present disclosure. As shown, a network node 702 and a network node 704 may communicate with one another. The network node 702 and/or 704 may be, or be similar, to the network node 102 and/or the network node 104 depicted in FIG. 1.

As shown by reference number 706, the network node 702 may transmit, and the network node 704 may receive, a nonlinear modeling capability indication associated with a nonlinear modeling configuration 710 of the network node 702. The nonlinear modeling capability indication may indicate, for example, that the network node 702 includes the nonlinear modeling configuration 710 described herein. The nonlinear modeling configuration may include at least one of a hardware configuration or a firmware configuration.

As shown, for example, the nonlinear modeling configuration 710 may include a reference signal processing component 712 that includes a coarse channel estimation component 714 configured to determine a coarse linear channel estimation based on the at least one DMRS. The reference signal processing component 712 may include a coarse channel equalization component 716 configured to determine an equalized coarse linear channel estimation based on the coarse linear channel estimation. The reference signal processing component 712 also may include a nonlinear modeling component 718 configured to determine a nonlinear model corresponding to a nonlinear distortion of the communication and a DPOD component 720 configured to determine a filtered coarse channel estimation based on the equalized coarse linear channel estimation and the nonlinear model. The nonlinear modeling configuration 710 also may include a fine channel estimation component 722 configured to determine a fine channel estimation based on the filtered coarse channel estimation.

As shown by reference number 708, the network node 704 may transmit, and the network node 702 may receive, a communication. The network node 702 may receive the communication in a slot and the communication may be transmitted based on the nonlinear modeling configuration. For example, the communication may include a data signal and at least one DMRS, where the at least one DMRS is associated with a single transmission power value.

In some aspects, receiving the communication may include detecting the communication (e.g., using an antenna), demodulating the communication and/or decoding the demodulated communication, as well as procedures implemented to facilitate one or more of the above. In some aspects, for example, the network node 702 may obtain a transformed communication using an FFT component 724. The transformed communication may be referred to herein as the “communication” for clarity of description. The communication may be provided to the reference signal processing component 712. The network node 702 may perform a symbol timing offset (STO) coarse channel estimation procedure using an STO coarse channel estimation component 726. The communication also may be provided to an STO coarse removal component 728. Together, the STO coarse channel estimation components 726 and 728 may remove an STO from the communication to facilitate analysis of the signal.

As shown, the communication is provided to the coarse channel estimation component 714, which generates a coarse channel estimation. For example, the coarse channel estimation component 714 may estimate a coarse linear chest (H_{coarse}) by using frequency domain filtering with a uniform frequency domain filter. If the communication includes more than one signal stream (e.g., if the communication is a MIMO communication), a pre-coding matrix removal component (“(P) removal”) 730 may be used to remove the pre-coding matrix from H_{coarse} by H_{raw}=P⁻¹. H_{coarse}. The resulting signal H_{raw} may be equalized using the coarse channel equalization component 716. The equalization procedure may be performed to identify the signal output corresponding to respective transmission ports.

As shown, the nonlinear modeling component 718 may be used to determine the determining a nonlinear model NL (Gi) per transmission port i. In some aspects, the network node 702 may determine the nonlinear model based on determining a plurality of estimated nonlinear distortion characteristics. Each respective estimated nonlinear distortion characteristic of the plurality of estimated nonlinear distortion characteristics may correspond to a respective transmission port of a plurality of transmission ports, as indicated above. In some aspects, the network node 702 may receive nonlinearity information associated with a transmission power amplifier nonlinear state corresponding to a transmission power amplifier of the network node 704. The network node 702 may average the nonlinear model over a plurality of slots based on the nonlinearity information. The plurality of slots may include the slot in which the communication is received. In some aspects, the nonlinearity information may indicate at least one of a coherency measure associated with the transmission power amplifier nonlinear state, a stability measure associated with the transmission power amplifier nonlinear state, or a quasi co-location associated with the transmission power amplifier nonlinear state.

As shown, the network node 702 may remove the nonlinear distortion during the channel estimation procedure based on a first DPOD procedure performed using the DPOD component 720. In some aspects, for example, the network node 702 may perform the first DPOD procedure for each transmission port to determine a filtered coarse channel estimation. In some aspects, the network node 702 may determine an intermediate fine channel estimation based on the filtered coarse channel estimation and may determine a fine channel estimation based on the intermediate fine channel estimation. For example, the network node 702 may use an STO fine channel estimation component 732 and an STO fine removal component 734 to remove a symbol timing offset. The network node 702 may use the fine channel estimation component 722 to estimate fine linear channel estimation (H_{fine}) by using an optimal frequency domain filtering (e.g., an optimal wiener filter for each resource block). In some aspects, the process of determining the coarse channel estimate, determining the nonlinear model, removing the nonlinearity from the coarse channel estimate, and determining a fine channel estimate may be referred to as a nonlinear model-based estimation procedure. The nonlinear model-based estimation procedure may be iterated any number of times. In some aspects, a quantity of iterations of the nonlinear model-based estimation procedure may be based on a quality associated with the filtered coarse channel estimation. As shown by the convolution operator in FIG. 7, the network node 702 may determine the fine channel estimation based on combining the intermediate fine channel estimation with the coarse linear channel estimation. Combining the intermediate fine channel estimation with the coarse linear channel estimation may include convolving the intermediate fine channel estimation with the coarse linear channel estimation.

An STO reintroduction component 736 may reintroduce the STO to the fine channel estimate, which may then be used by an equalizer 738 to equalize a received data signal corresponding to the at least one DMRS. A pre-coding matrix equalizer 740 may be used to equalize the signal if the signal is a MIMO signal and may provide output to a second DPOD 742. The second DPOD may utilize the nonlinear model determined by the nonlinear modeling component 718 to perform a second DPOD procedure associated with the data signal. The second DPOD procedure and equalization may be iterated a number of times and the output may be provided to a demapper and/or a decoder, as shown by block 744.

As indicated above. FIG. 7 is provided as an example. Other examples may differ from what is described with regard to FIG. 7.

FIG. 8 is a diagram illustrating an example process 800 performed, for example, by a network node, in accordance with the present disclosure. Example process 800 is an example where the network node (e.g., network node 702) performs operations associated with nonlinear modeling for channel estimation.

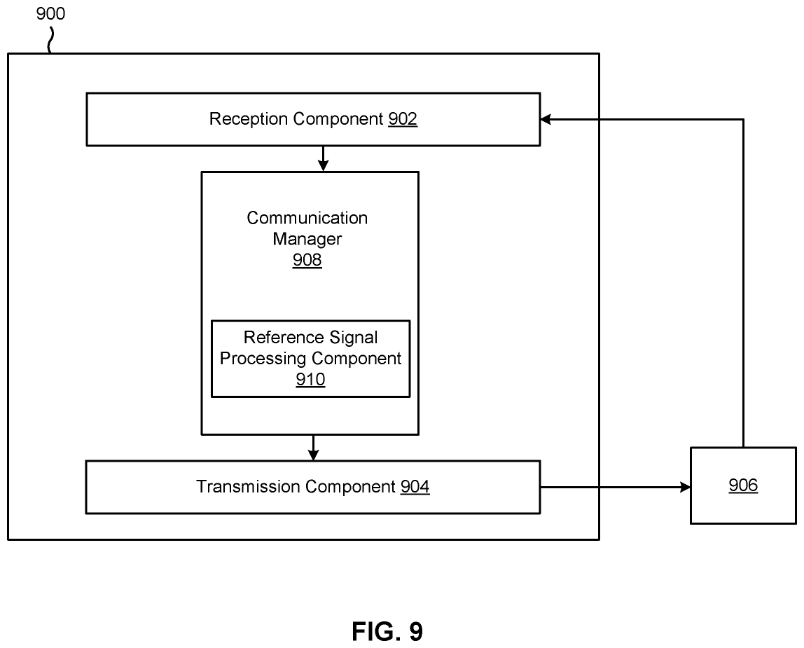

As shown in FIG. 8, in some aspects, process 800 may include transmitting a nonlinear modeling capability indication associated with a nonlinear modeling configuration of the network node (block 810). For example, the network node (e.g., using communication manager 908 and/or transmission component 904, depicted in FIG. 9) may transmit a nonlinear modeling capability indication associated with a nonlinear modeling configuration of the network node, as described above.

As further shown in FIG. 8, in some aspects, process 800 may include receiving, based on the nonlinear modeling capability indication, a communication in a slot, wherein the communication includes a data signal and at least one DMRS, wherein the at least one DMRS is associated with a single transmission power value (block 820). For example, the network node (e.g., using communication manager 908 and/or reception component 902, depicted in FIG. 9) may receive, based on the nonlinear modeling capability indication, a communication in a slot, wherein the communication includes a data signal and at least one DMRS, wherein the at least one DMRS is associated with a single transmission power value, as described above.

Process 800 may include additional aspects, such as any single aspect or any combination of aspects described below and/or in connection with one or more other processes described elsewhere herein.

In a first aspect, the nonlinear modeling configuration comprises at least one of a hardware configuration or a firmware configuration. In a second aspect, alone or in combination with the first aspect, the nonlinear modeling configuration comprises a reference signal processing component that includes a coarse channel estimation component configured to determine a coarse linear channel estimation based on the at least one DMRS, a coarse channel equalization component configured to determine an equalized coarse linear channel estimation based on the coarse linear channel estimation, a nonlinear modeling component configured to determine a nonlinear model corresponding to a nonlinear distortion of the communication, a DPOD component configured to determine a filtered coarse channel estimation based on the equalized coarse linear channel estimation and the nonlinear model, and a fine channel estimation component configured to determine a fine channel estimation based on the filtered coarse channel estimation.

In a third aspect, alone or in combination with one or more of the first and second aspects, process 800 includes determining, based on the at least one DMRS, a nonlinear model corresponding to a nonlinear distortion of the communication, removing the nonlinear distortion during a channel estimation procedure based on a first DPOD procedure, and processing the data signal based on the nonlinear model and a second DPOD procedure. In a fourth aspect, alone or in combination with the third aspect, the second DPOD procedure is based on the nonlinear model. In a fifth aspect, alone or in combination with one or more of the third or fourth aspects, the nonlinear distortion comprises power amplifier-induced distortion. In a sixth aspect, alone or in combination with one or more of the third through fifth aspects, determining the nonlinear model comprises processing the at least one DMRS. In a seventh aspect, alone or in combination with the sixth aspect, processing the at least one DMRS comprises determining a coarse linear channel estimation based on a transformed DMRS of the at least one DMRS, wherein the transformed DMRS comprises a frequency domain representation of the at least one DMRS, determining an equalized coarse linear channel estimation, and determining a fine channel estimation based on a non-linear model-based estimation procedure.

In an eighth aspect, alone or in combination with the seventh aspect, the non-linear model-based estimation procedure comprises determining a nonlinear model based on the equalized coarse linear channel estimation, determining a filtered coarse channel estimation by performing the first DPOD procedure based on the nonlinear model and the equalized coarse linear channel estimation, determining an intermediate fine channel estimation based on the filtered coarse channel estimation, and determining a fine channel estimation based on the intermediate fine channel estimation. In a ninth aspect, alone or in combination with the eighth aspect, process 800 includes performing a plurality of iterations of the non-linear model-based estimation procedure.

In a tenth aspect, alone or in combination with the ninth aspect, a quantity of iterations of the plurality of iterations is based on a quality associated with the filtered coarse channel estimation. In an eleventh aspect, alone or in combination with one or more of the eighth through tenth aspects, determining the fine channel estimation comprises combining the intermediate fine channel estimation with the coarse linear channel estimation. In a twelfth aspect, alone or in combination with one or more of the eighth through eleventh aspects, determining the nonlinear model comprises determining a plurality of estimated nonlinear distortion characteristics, wherein each respective estimated nonlinear distortion characteristic of the plurality of estimated nonlinear distortion characteristics corresponds to a respective transmission port of a plurality of transmission ports. In a thirteenth aspect, alone or in combination with the twelfth aspect, performing the first DPOD procedure comprises performing DPOD filtering associated with each transmission port of the plurality of transmission ports. In a fourteenth aspect, alone or in combination with one or more of the eighth through thirteenth aspects, determining the equalized coarse linear channel estimation comprises removing a precoding matrix.

In a fifteenth aspect, alone or in combination with one or more of the third through fourteenth aspects, process 800 includes receiving nonlinearity information associated with a transmission power amplifier nonlinear state and averaging the nonlinear model over a plurality of slots based on the nonlinearity information, wherein the plurality of slots includes the slot. In a sixteenth aspect, alone or in combination with the fifteenth aspect, the nonlinearity information indicates at least one of a coherency measure associated with the transmission power amplifier nonlinear state, a stability measure associated with the transmission power amplifier nonlinear state, or a quasi co-location associated with the transmission power amplifier nonlinear state.

Although FIG. 8 shows example blocks of process 800, in some aspects, process 800 may include additional blocks, fewer blocks, different blocks, or differently arranged blocks than those depicted in FIG. 8. Additionally, or alternatively, two or more of the blocks of process 800 may be performed in parallel.

FIG. 9 is a diagram of an example apparatus 900 for wireless communication. The apparatus 900 may be a network node, or a network node may include the apparatus 900. In some aspects, the apparatus 900 may be, be similar to, include, or be included in the network node 102, the network node 104, the network node 702, the network node 704, the apparatus 200, a UE 320, and/or a base station 310, among other examples. In some aspects, the apparatus 900 includes a reception component 902 and a transmission component 904, which may be in communication with one another (for example, via one or more buses and/or one or more other components). As shown, the apparatus 900 may communicate with another apparatus 906 (such as a UE, a base station, or another wireless communication device) using the reception component 902 and the transmission component 904. As further shown, the apparatus 900 may include the communication manager 908. The communication manager 908 may include a reference signal processing component 910, among other examples.

In some aspects, the apparatus 900 may be configured to perform one or more operations described herein in connection with FIGS. 6 and 7. Additionally, or alternatively, the apparatus 900 may be configured to perform one or more processes described herein, such as process 800 of FIG. 8. In some aspects, the apparatus 900 and/or one or more components shown in FIG. 9 may include one or more components of the apparatus 200 described in connection with FIG. 2, the network node 402 described in connection with FIG. 4 and/or the network node 704 described in connection with FIG. 4. Additionally, or alternatively, one or more components shown in FIG. 9 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 902 may receive communications, such as reference signals, control information, data communications, or a combination thereof, from the apparatus 906. The reception component 902 may provide received communications to one or more other components of the apparatus 900. In some aspects, the reception component 902 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 900. In some aspects, the reception component 902 may include one or more antennas, a modem, a demodulator, a MIMO detector, a receive processor, a controller/processor, a memory, or a combination thereof, of the network node 402 and/or 404 described in connection with FIG. 4.

The transmission component 904 may transmit communications, such as reference signals, control information, data communications, or a combination thereof, to the apparatus 906. In some aspects, one or more other components of the apparatus 900 may generate communications and may provide the generated communications to the transmission component 904 for transmission to the apparatus 906. In some aspects, the transmission component 904 may perform signal processing on the generated communications (such as filtering, amplification, modulation, digital-to-analog conversion, multiplexing, interleaving, mapping, or encoding, among other examples), and may transmit the processed signals to the apparatus 906. In some aspects, the transmission component 904 may include one or more antennas, a modem, a modulator, a transmit MIMO processor, a transmit processor, a controller/processor, a memory, or a combination thereof, of the network node 402 and/or 404 described in connection with FIG. 4. In some aspects, the transmission component 904 may be co-located with the reception component 902 in a transceiver.

The transmission component 904 may transmit a nonlinear modeling capability indication associated with a nonlinear modeling configuration of the network node. The reception component 902 may receive, based on the nonlinear modeling capability indication, a communication in a slot, wherein the communication includes a data signal and at least one DMRS, wherein the at least one DMRS is associated with a single transmission power value.

The communication manager 908 and/or the reference signal processing component 910 may determine, based on the at least one DMRS, a nonlinear model corresponding to a nonlinear distortion of the communication. In some aspects, the communication manager 908 may include one or more antennas, a modem, a controller/processor, a memory, or a combination thereof, of the apparatus 200 described in connection with FIG. 2, the network node 402 described in connection with FIG. 4 and/or the network node 704 described in connection with FIG. 4. In some aspects, the communication manager 908 may include the reception component 902 and/or the transmission component 904. In some aspects, the reference signal processing component 910 may include one or more antennas, a modem, a controller/processor, a memory, or a combination thereof, of the apparatus 200 described in connection with FIG. 2, the network node 402 described in connection with FIG. 4 and/or the network node 704 described in connection with FIG. 4. In some aspects, the reference signal processing component 910 may include the reception component 902 and/or the transmission component 904

The communication manager 908 and/or the reference signal processing component 910 may remove the nonlinear distortion during a channel estimation procedure based on a first DPOD procedure. The communication manager 908 and/or the reference signal processing component 910 may process the data signal based on the nonlinear model and a second DPOD procedure. The communication manager 908 and/or the reference signal processing component 910 may perform a plurality of iterations of the non-linear model-based estimation procedure. The reception component 902 may receive nonlinearity information associated with a transmission power amplifier nonlinear state. The communication manager 908 and/or the reference signal processing component 910 may average the nonlinear model over a plurality of slots based on the nonlinearity information, wherein the plurality of slots includes the slot.

The number and arrangement of components shown in FIG. 9 are provided as an example. In practice, there may be additional components, fewer components, different components, or differently arranged components than those shown in FIG. 9. Furthermore, two or more components shown in FIG. 9 may be implemented within a single component, or a single component shown in FIG. 9 may be implemented as multiple, distributed components. Additionally, or alternatively, a set of (one or more) components shown in FIG. 9 may perform one or more functions described as being performed by another set of components shown in FIG. 9.

The following provides an overview of some Aspects of the present disclosure:

Aspect 1: A method of wireless communication performed by a network node, comprising: transmitting a nonlinear modeling capability indication associated with a nonlinear modeling configuration of the network node; and receiving, based on the nonlinear modeling capability indication, a communication in a slot, wherein the communication includes a data signal and at least one demodulation reference signal (DMRS), wherein the at least one DMRS is associated with a single transmission power value.

Aspect 2: The method of Aspect 1, wherein the nonlinear modeling configuration comprises at least one of a hardware configuration or a firmware configuration.

Aspect 3: The method of Aspect 1, wherein the nonlinear modeling configuration comprises a reference signal processing component that includes: a coarse channel estimation component configured to determine a coarse linear channel estimation based on the at least one DMRS: a coarse channel equalization component configured to determine an equalized coarse linear channel estimation based on the coarse linear channel estimation: a nonlinear modeling component configured to determine a nonlinear model corresponding to a nonlinear distortion of the communication: a digital post distortion (DPOD) component configured to determine a filtered coarse channel estimation based on the equalized coarse linear channel estimation and the nonlinear model; and a fine channel estimation component configured to determine a fine channel estimation based on the filtered coarse channel estimation.

Aspect 4: The method of any of Aspects 1-3, further comprising: determining, based on the at least one DMRS, a nonlinear model corresponding to a nonlinear distortion of the communication: removing the nonlinear distortion during a channel estimation procedure based on a first digital post distortion (DPOD) procedure; and processing the data signal based on the nonlinear model and a second DPOD procedure.

Aspect 5: The method of Aspect 4, wherein the second DPOD procedure is based on the nonlinear model.

Aspect 6: The method of either of Aspects 4 or 5, wherein the nonlinear distortion comprises power amplifier-induced distortion.

Aspect 7: The method of any of Aspects 4-6, wherein determining the nonlinear model comprises processing the at least one DMRS.

Aspect 8: The method of Aspect 7, wherein processing the at least one DMRS comprises: determining a coarse linear channel estimation based on a transformed DMRS of the at least one DMRS, wherein the transformed DMRS comprises a frequency domain representation of the at least one DMRS: determining an equalized coarse linear channel estimation; and determining a fine channel estimation based on a non-linear model-based estimation procedure.

Aspect 9: The method of Aspect 8, wherein the non-linear model-based estimation procedure comprises: determining a nonlinear model based on the equalized coarse linear channel estimation: determining a filtered coarse channel estimation by performing the first DPOD procedure based on the nonlinear model and the equalized coarse linear channel estimation: determining an intermediate fine channel estimation based on the filtered coarse channel estimation; and determining a fine channel estimation based on the intermediate fine channel estimation.

Aspect 10: The method of Aspect 9, further comprising performing a plurality of iterations of the non-linear model-based estimation procedure.

Aspect 11: The method of Aspect 10, wherein a quantity of iterations of the plurality of iterations is based on a quality associated with the filtered coarse channel estimation.

Aspect 12: The method of any of Aspects 9-11, wherein determining the fine channel estimation comprises combining the intermediate fine channel estimation with the coarse linear channel estimation.

Aspect 13: The method of any of Aspects 9-12, wherein determining the nonlinear model comprises determining a plurality of estimated nonlinear distortion characteristics, wherein each respective estimated nonlinear distortion characteristic of the plurality of estimated nonlinear distortion characteristics corresponds to a respective transmission port of a plurality of transmission ports.

Aspect 14: The method of Aspect 13, wherein performing the first DPOD procedure comprises performing DPOD filtering associated with each transmission port of the plurality of transmission ports.

Aspect 15: The method of any of Aspects 9-14, wherein determining the equalized coarse linear channel estimation comprises removing a precoding matrix.

Aspect 16: The method of any of Aspects 4-15, further comprising: receiving nonlinearity information associated with a transmission power amplifier nonlinear state; and averaging the nonlinear model over a plurality of slots based on the nonlinearity information, wherein the plurality of slots includes the slot.

Aspect 17: The method of Aspect 16, wherein the nonlinearity information indicates at least one of: a coherency measure associated with the transmission power amplifier nonlinear state, a stability measure associated with the transmission power amplifier nonlinear state, or a quasi co-location associated with the transmission power amplifier nonlinear state.

Aspect 18: An apparatus for wireless communication at a device, comprising a processor: memory coupled with the processor; and instructions stored in the memory and executable by the processor to cause the apparatus to perform the method of one or more of Aspects 1-17.

Aspect 19: A device for wireless communication, comprising a memory and one or more processors coupled to the memory, the one or more processors configured to perform the method of one or more of Aspects 1-17.

Aspect 20: An apparatus for wireless communication, comprising at least one means for performing the method of one or more of Aspects 1-17.

Aspect 21: A non-transitory computer-readable medium storing code for wireless communication, the code comprising instructions executable by a processor to perform the method of one or more of Aspects 1-17.

Aspect 22: A non-transitory computer-readable medium storing a set of instructions for wireless communication, the set of instructions comprising one or more instructions that, when executed by one or more processors of a device, cause the device to perform the method of one or more of Aspects 1-17.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

What is claimed is:

1. A network node for wireless communication, comprising:
a memory; and
one or more processors coupled to the memory and configured to cause the network node to:
transmit a nonlinear modeling capability indication associated with a nonlinear modeling configuration of the network node; and
receive, based on the nonlinear modeling capability indication, a communication in a slot, wherein the communication includes a data signal and at least one demodulation reference signal (DMRS), wherein the at least one DMRS is associated with a single transmission power value.

2. The network node of claim 1, wherein the nonlinear modeling configuration comprises at least one of a hardware configuration or a firmware configuration.

3. The network node of claim 1, wherein the nonlinear modeling configuration comprises a first reference signal processing component that includes:
a coarse channel estimation component configured to determine a coarse linear channel estimation based on the at least one DMRS;
a coarse channel equalization component configured to determine an equalized coarse linear channel estimation based on the coarse linear channel estimation;
a nonlinear modeling component configured to determine a nonlinear model corresponding to a nonlinear distortion of the communication;
a digital post distortion (DPOD) component configured to determine a filtered coarse channel estimation based on the equalized coarse linear channel estimation and the nonlinear model; and
a fine channel estimation component configured to determine a fine channel estimation based on the filtered coarse channel estimation.

4. The network node of claim 1, wherein the one or more processors are further configured to cause the network node to:
determine, based on the at least one DMRS, a nonlinear model corresponding to a nonlinear distortion of the communication:
remove the nonlinear distortion during a channel estimation procedure based on a first digital post distortion (DPOD) procedure; and
process the data signal based on the nonlinear model and a second DPOD procedure.

5. The network node of claim 4, wherein the second DPOD procedure is based on the nonlinear model.

6. The network node of claim 4, wherein the nonlinear distortion comprises power amplifier-induced distortion.

7. The network node of claim 4, wherein the one or more processors, to cause the network node to determine the nonlinear model, are configured to cause the network node to process the at least one DMRS.

8. The network node of claim 7, wherein the one or more processors, to cause the network node to process the at least one DMRS, are configured to cause the network node to:
determine a coarse linear channel estimation based on a transformed DMRS of the at least one DMRS, wherein the transformed DMRS comprises a frequency domain representation of the at least one DMRS;
determine an equalized coarse linear channel estimation; and
determine a fine channel estimation based on a non-linear model-based estimation procedure.

9. The network node of claim 8, wherein the one or more processors, to determine the fine channel estimation based on the non-linear model-based estimation procedure, the one or more processors are configured to cause the network node to:
determine a nonlinear model based on the equalized coarse linear channel estimation:
determine a filtered coarse channel estimation by performing the first DPOD procedure based on the nonlinear model and the equalized coarse linear channel estimation;
determine an intermediate fine channel estimation based on the filtered coarse channel estimation; and
determine a fine channel estimation based on the intermediate fine channel estimation.

10. The network node of claim 9, wherein the one or more processors are further configured to cause the network node to perform a plurality of iterations of the non-linear model-based estimation procedure.

11. The network node of claim 10, wherein a quantity of iterations of the plurality of iterations is based on a quality associated with the filtered coarse channel estimation.

12. The network node of claim 9, wherein the one or more processors, to cause the network node to determine the fine channel estimation, are configured to cause the network node to combine the intermediate fine channel estimation with the coarse linear channel estimation.

13. The network node of claim 9, wherein the one or more processors, to cause the network node to determine the nonlinear model, are configured to cause the network node to determine a plurality of estimated nonlinear distortion characteristics, wherein each respective estimated nonlinear distortion characteristic of the plurality of estimated nonlinear distortion characteristics corresponds to a respective transmission port of a plurality of transmission ports.

14. The network node of claim 13, wherein the one or more processors, to cause the network node to perform the first DPOD procedure, are configured to cause the network node to perform DPOD filtering associated with each transmission port of the plurality of transmission ports.

15. The network node of claim 9, wherein the one or more processors, to cause the network node to determine the equalized coarse linear channel estimation, are configured to cause the network node to remove a precoding matrix.

16. The network node of claim 4, wherein the one or more processors are further configured to cause the network node to:
receive nonlinearity information associated with a transmission power amplifier nonlinear state; and
average the nonlinear model over a plurality of slots based on the nonlinearity information, wherein the plurality of slots includes the slot.

17. The network node of claim 16, wherein the nonlinearity information indicates at least one of: a coherency measure associated with the transmission power amplifier nonlinear state, a stability measure associated with the transmission power amplifier nonlinear state, or a quasi co-location associated with the transmission power amplifier nonlinear state.

18. A method of wireless communication performed by a network node, comprising:
transmitting a nonlinear modeling capability indication associated with a nonlinear modeling configuration of the network node; and
receiving, based on the nonlinear modeling capability indication, a communication in a slot, wherein the communication includes a data signal and at least one demodulation reference signal (DMRS), wherein the at least one DMRS is associated with a single transmission power value.

19. The method of claim 18, wherein the nonlinear modeling configuration comprises a reference signal processing component that includes:
a coarse channel estimation component configured to determine a coarse linear channel estimation based on the at least one DMRS:
a coarse channel equalization component configured to determine an equalized coarse linear channel estimation based on the coarse linear channel estimation:
a nonlinear modeling component configured to determine a nonlinear model corresponding to a nonlinear distortion of the communication;
a digital post distortion (DPOD) component configured to determine a filtered coarse channel estimation based on the equalized coarse linear channel estimation and the nonlinear model; and
a fine channel estimation component configured to determine a fine channel estimation based on the filtered coarse channel estimation.

20. The method of claim 18, further comprising:
determining, based on the at least one DMRS, a nonlinear model corresponding to a nonlinear distortion of the communication;
removing the nonlinear distortion during a channel estimation procedure based on a first digital post distortion (DPOD) procedure; and
processing the data signal based on the nonlinear model and a second DPOD procedure.

21. The method of claim 20, wherein determining the nonlinear model comprises processing the at least one DMRS, and wherein processing the at least one DMRS comprises:
determining a coarse linear channel estimation based on a transformed DMRS of the at least one DMRS, wherein the transformed DMRS comprises a frequency domain representation of the at least one DMRS:
determining an equalized coarse linear channel estimation; and
determining a fine channel estimation based on a non-linear model-based estimation procedure.

22. The method of claim 21, wherein the non-linear model-based estimation procedure comprises:
determining a nonlinear model based on the equalized coarse linear channel estimation;
determining a filtered coarse channel estimation by performing the first DPOD procedure based on the nonlinear model and the equalized coarse linear channel estimation;
determining an intermediate fine channel estimation based on the filtered coarse channel estimation; and
determining a fine channel estimation based on the intermediate fine channel estimation.

23. The method of claim 22, wherein determining the fine channel estimation comprises combining the intermediate fine channel estimation with the coarse linear channel estimation.

24. The method of claim 22, wherein determining the nonlinear model comprises determining a plurality of estimated nonlinear distortion characteristics, wherein each respective estimated nonlinear distortion characteristic of the plurality of estimated nonlinear distortion characteristics corresponds to a respective transmission port of a plurality of transmission ports.

25. The method of claim 22, wherein determining the equalized coarse linear channel estimation comprises removing a precoding matrix.

26. The method of claim 20, further comprising:
receiving nonlinearity information associated with a transmission power amplifier nonlinear state; and
averaging the nonlinear model over a plurality of slots based on the nonlinearity information, wherein the plurality of slots includes the slot.

27. A non-transitory computer-readable medium having instructions stored thereon that, when executed, cause a network node to:
transmit a nonlinear modeling capability indication associated with a nonlinear modeling configuration of the network node; and
receive, based on the nonlinear modeling capability indication, a communication in a slot, wherein the communication includes a data signal and at least one demodulation reference signal (DMRS), wherein the at least one DMRS is associated with a single transmission power value.

28. The non-transitory computer-readable medium of claim 27, wherein the nonlinear modeling configuration comprises a reference signal processing component that includes:
a coarse channel estimation component configured to determine a coarse linear channel estimation based on the at least one DMRS;
a coarse channel equalization component configured to determine an equalized coarse linear channel estimation based on the coarse linear channel estimation;
a nonlinear modeling component configured to determine a nonlinear model corresponding to a nonlinear distortion of the communication;
a digital post distortion (DPOD) component configured to determine a filtered coarse channel estimation based on the equalized coarse linear channel estimation and the nonlinear model; and
a fine channel estimation component configured to determine a fine channel estimation based on the filtered coarse channel estimation.

29. An apparatus for wireless communication, comprising:
means for transmitting a nonlinear modeling capability indication associated with a nonlinear modeling configuration of the apparatus; and
means for receiving, based on the nonlinear modeling capability indication, a communication in a slot, wherein the communication includes a data signal and at least one demodulation reference signal (DMRS), wherein the at least one DMRS is associated with a single transmission power value.

30. The apparatus of claim 29, wherein the nonlinear modeling configuration comprises a reference signal processing component that includes:
a coarse channel estimation component configured to determine a coarse linear channel estimation based on the at least one DMRS:
a coarse channel equalization component configured to determine an equalized coarse linear channel estimation based on the coarse linear channel estimation;
a nonlinear modeling component configured to determine a nonlinear model corresponding to a nonlinear distortion of the communication;
a digital post distortion (DPOD) component configured to determine a filtered coarse channel estimation based on the equalized coarse linear channel estimation and the nonlinear model; and
a fine channel estimation component configured to determine a fine channel estimation based on the filtered coarse channel estimation.
